(19) United States
(12) Patent Application Publication
(10) Pub. No.: US 2015/0260776 A1
(43) Pub. Date: Sep. 17, 2015

(54) METHOD AND APPARATUS FOR EVALUATING ELECTRICAL WIRE

(71) Applicant: Hitachi Metals, Ltd., Tokyo (JP)

(72) Inventors: Peng Xie, Hitachi (JP); Hideyuki Kikuchi, Hitachi (JP); Yosuke Sumi, Hitachi (JP)

(21) Appl. No.: 14/638,976

(22) Filed: Mar. 4, 2015

(30) Foreign Application Priority Data
Mar. 13, 2014 (JP) 2014-49760

(51) Int. Cl. G01R 31/02; G01R 31/12

(52) U.S. Cl. CPC G01R 31/021; G01R 31/12

(57) ABSTRACT

A method for evaluating an electrical wire having a conductor and an insulating layer includes: a partial-discharge amount-of-charge determining step of applying, by a voltage application unit, a voltage to the electrical wire to cause partial discharge in the electrical wire and determining an amount of charge owing to the partial discharge; and an evaluation step of evaluating the insulating layer by using a change over time in the amount of charge owing to the partial discharge.

The present application is based on Japanese patent application No. 2014-49760 filed on Mar. 13, 2014, the entire contents of which are incorporated herein by reference.

### BACKGROUND OF THE INVENTION

1. Field of the Invention

The present invention relates to a method and an apparatus for evaluating an electrical wire having a conductor and an insulating layer.

2. Description of the Related Art

For example, to evaluate an electrical wire having a conductor and an insulating layer, a material (a composition or a formation material) of the electrical wire may be estimated. In general, the material of an insulating layer is estimated by removing a portion of the insulating layer from the conductor and performing chemical or physical testing on the removed insulating layer. The material of the insulating layer is estimated using, for example, a reagent.

### SUMMARY OF THE INVENTION

However, when the material of an insulating layer is estimated through artificial measurement, such as the aforementioned chemical or physical testing, the result of the evaluation varies depending on the test conditions (e.g., the temperature and the density of the reagent) and so on, and there are cases in which accurate estimation cannot be performed. For a thin electrical wire having an insulating layer thickness of tens of micrometers, such as an enameled wire, there are cases in which it is difficult to remove an insulating layer from a conductor.

Accordingly, an object of the present invention is to overcome the foregoing problems and to easily and accurately evaluate an electrical wire.

(1) According to one aspect of the present invention, there is provided a method for evaluating an electrical wire having a conductor and an insulating layer. The method includes: a partial-discharge amount-of-charge determining step of applying, by a voltage application unit, a voltage to the electrical wire to cause partial discharge in the electrical wire and determining an amount of charge owing to the partial discharge; and an evaluation step of evaluating the insulating layer by using a change over time in the amount of charge owing to the partial discharge.

In the above exemplary invention (1), many exemplary modifications and changes can be made as below the following exemplary modifications and changes can be made.

(i) An amount-of-change determining step of determining an amount of change over time in the amount of charge determined in the partial-discharge amount-of-charge determining step, wherein, in the evaluation step, correlation information about the amount of change is obtained, and the insulating layer is evaluated by using the amount of change, based on the correlation information.

(ii) In the evaluation step, information for identifying a material of the insulating layer by using the amount of change is obtained as the correlation information, and the amount of change determined in the amount-of-change determining step is compared with the correlation information to estimate the material of the insulating layer.

(iii) A correlation-information generation step of continuously detecting, for a predetermined time, an amount of charge owing to partial discharge in another electrical wire having a same type of insulating layer as the insulating layer in the electrical wire, generating the correlation information by using a result of the detection, and storing and holding the correlation information, wherein, in the evaluation step, the correlation information is obtained by reading the correlation information stored and held in the correlation-information generation step.

(2) According to another aspect of the present invention, there is provided an apparatus for evaluating an electrical wire. The apparatus includes: a voltage application unit that applies a voltage to an electrical wire having a conductor and an insulating layer; a partial-discharge amount-of-charge determining unit that determines an amount of charge owing to partial discharge that occurs in the electrical wire; and an evaluation unit that evaluates the insulating layer by using a change over time in the amount of charge owing to the partial discharge.

### Points of the Invention

According to the present invention, it is possible to easily and accurately evaluate an electrical wire.

### BRIEF DESCRIPTION OF THE DRAWINGS

The foregoing and other exemplary purposes, aspects and advantages will be better understood from the following detailed description of the invention with reference to the drawings, in which:

FIG. 1 is a block diagram illustrating one example of a schematic configuration of a control unit included in an evaluation apparatus according to one embodiment of the present invention;

FIG. 2 is a schematic diagram illustrating one example of a circuit configuration of the evaluation apparatus according to the embodiment of the present invention;

FIG. 3 is a graph illustrating one example of data (waveform data) recorded by a partial-discharge waveform recording unit included in the evaluation apparatus according to the embodiment of the present invention;

FIG. 4 is a graph illustrating one example of data (waveform data) created by a partial-discharge amount-of-charge determining unit included in the evaluation apparatus according to the embodiment of the present invention; and

FIG. 5 is a flow diagram illustrating an evaluation process for an electrical wire according to the embodiment of the present invention.

### DESCRIPTION OF THE PREFERRED EMBODIMENTS

### Finding Made by the Present Inventors

First, a finding made by the present inventors will first be described before an embodiment of the present invention is described. The present inventors have carried out extensive and earnest study on a relationship between a material of an insulating layer in an electrical wire having a conductor and an insulating layer and a partial-discharge amount-of-charge. As a result, the present inventors have found that there is a correlation between the partial-discharge amount-of-charge in the electrical wire and the material of the insulating layer. The term “partial-discharge amount-of-charge” as used herein refers to the amount of electrical charge that is generated in an electrical wire owing to partial discharge in the electrical wire when a voltage application unit applies a voltage higher than a partial discharge inception voltage of the electrical wire to the electrical wire to cause the partial discharge in the electrical wire. The present invention is based on the above-described finding made by the present inventors.

### One Embodiment of Present Invention

### (1) Configuration of Evaluation Apparatus

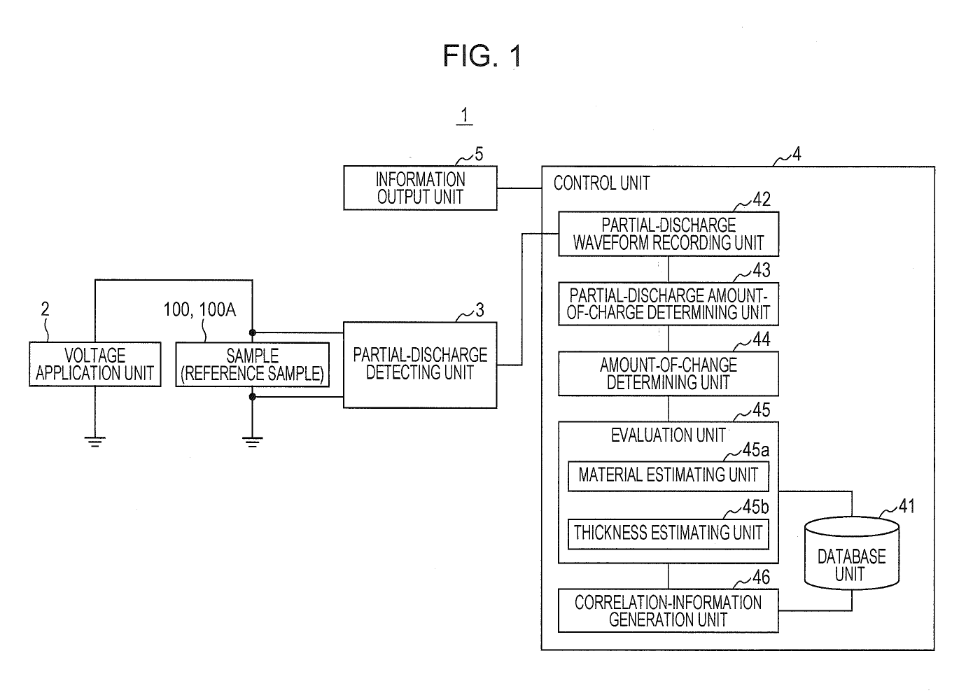

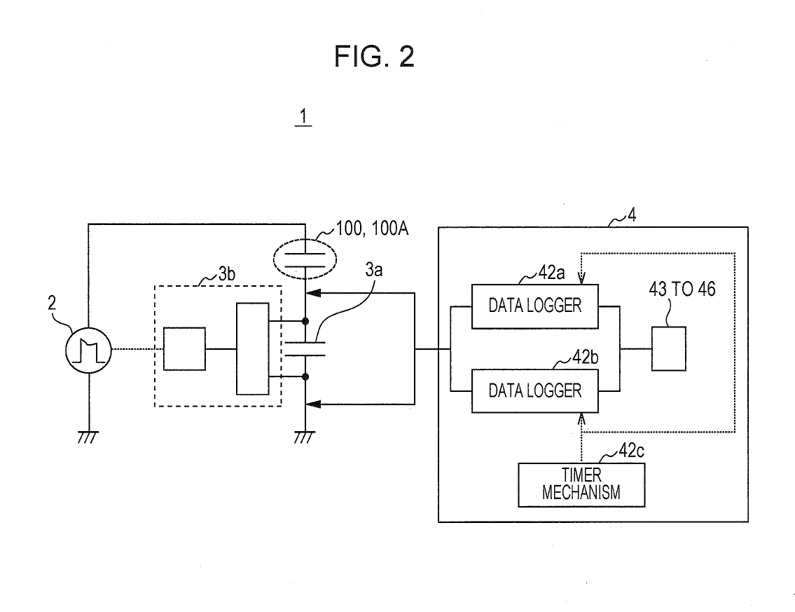

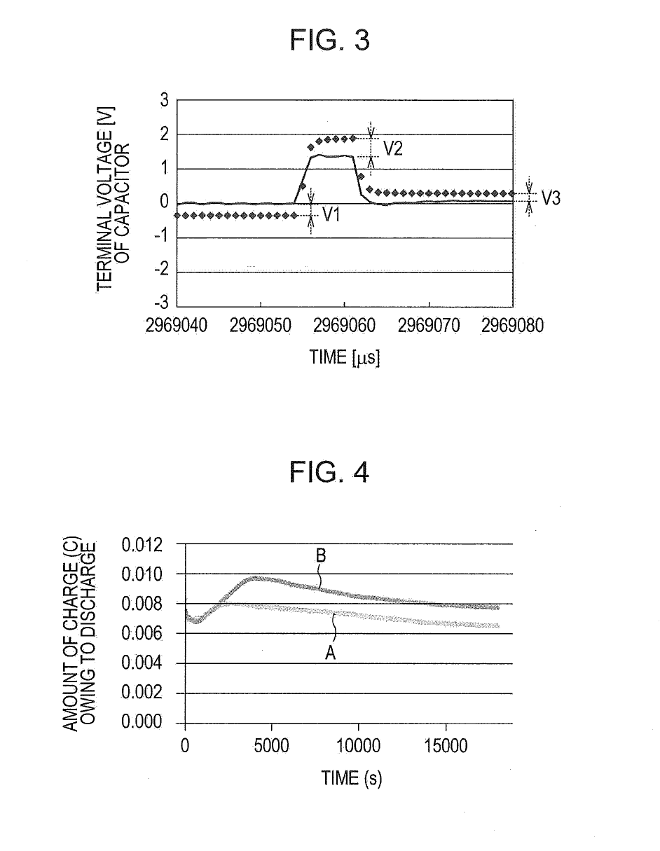

An evaluation apparatus according to one embodiment of the present invention will be described with reference to FIGS. 1 to 4. FIG. 1 is a block diagram illustrating an example of a schematic configuration of an evaluation apparatus according to the present embodiment. FIG. 2 is a schematic diagram illustrating an example of a circuit configuration of the evaluation apparatus according to the present embodiment. FIG. 3 is a graph illustrating one example of data (waveform data) recorded by a partial-discharge waveform recording unit included in the evaluation apparatus according to the present embodiment. FIG. 4 is a graph illustrating one example of data (waveform data) created by a partial-discharge amount-of-charge determining unit included in the evaluation apparatus according to the present embodiment. A description below will be given of an example of a case in which an evaluation apparatus 1 evaluates an electrical wire 100 by estimating a material of an insulating layer in the electrical wire 100.

### (Voltage Application Unit)

As illustrated in FIGS. 1 and 2, the evaluation apparatus 1 has a voltage application unit 2 that applies a voltage to the electrical wire 100 (hereinafter also referred to as a “sample 100”) to be evaluated. The voltage application unit 2 is configured so as to apply, for example, a voltage higher than a partial discharge inception voltage (hereinafter referred to as “PDIV”) of the sample 100 to the sample 100. Application of the voltage higher than the PDIV to the sample 100 makes it possible to cause partial discharge in the sample 100. The voltage application unit 2 may be implemented by a voltage application device, such as an inverter pulse generator or a surge pulse generator. That is, the voltage applied from the voltage application unit 2 to the sample 100 is, for example, an inverter surge pulse, an alternating-current voltage, or an impulse voltage. The sample 100 is placed between the voltage application unit 2 and ground (earth). The sample 100 may be any sample having a conductor and an insulating layer. Examples of the sample 100 include an enameled wire, a twisted wire, and a twisted pair wire (a twisted pair cable).

### (Partial-Discharge Detecting Unit)

The evaluation apparatus 1 has a partial-discharge detecting unit 3. The partial-discharge detecting unit 3 is configured so as to detect partial discharge that occurs in the sample 100, for example, by using a residual-voltage detection circuit based on a residual charge method. For example, the partial-discharge detecting unit 3 is configured so as to detect charge generated in the sample 100 owing to the occurrence of the partial discharge, through use of a capacitor 3a (see FIG. 2). The capacitor 3a is connected in series between the sample 100 and ground (earth). The capacitor 3a is to store charge generated in the sample 100 owing to the occurrence of partial discharge. It is desirable that the capacitor 3a have a larger electrostatic capacitance than the electrostatic capacitance of the sample 100 so that the majority of the voltage is applied to the sample 100. Also, a control unit 4 (a partial-discharge waveform recording unit 42) described below is electrically connected to the partial-discharge detecting unit 3.

A short-circuiting circuit (refresh circuit) 3b for periodically refreshing charge excessively accumulated in the capacitor 3a is connected to two opposite ends of the capacitor 3a (see FIG. 2). The short-circuiting circuit 3b is configured so as to short-circuit the two-opposite ends of the capacitor 3a to thereby discharge the capacitor 3a. For example, the short-circuiting circuit 3b is configured so as to short-circuit the two opposite ends of the capacitor 3a at predetermined time intervals from when the voltage application unit 2 starts applying a voltage to the sample 100. Also, the short-circuiting circuit 3b is configured so as to output, in synchronization with an inverter pulse output from the voltage application unit 2, a drive pulse (e.g., with a width of a 1 ms) when a certain time passes after the pulse rises, to operate a relay to thereby short-circuit the two opposite ends of the capacitor 3a.

Mainly, the capacitor 3a constitutes the partial-discharge detecting unit 3. The partial-discharge detecting unit 3 may be regarded as being included in the short-circuiting circuit 3b.

### (Control Unit)

The evaluation apparatus 1 has the control unit 4. The control unit 4 is configured so as to perform necessary processing in order to estimate (evaluate) a material of an insulating layer in the sample 100. The control unit 4 may be realized using a computer apparatus that executes a predetermined program. That is, the control unit 4 is configured as a computer including a combination of, for example, a central processing unit (CPU), a random access memory (RAM), and a hard disk drive (HDD) or the like, which serves as a database unit (a storage device) 41. The computer apparatus may be constituted by a single apparatus or may be constituted by a plurality of apparatuses connected through a communication channel. When the computer apparatus is constituted by a plurality of apparatuses, the functions of units described below may be arranged in a distributed manner.

The control unit 4 is configured so that a program stored in a database unit 41 is read and executed to realize a partial-discharge waveform recording function provided by the partial-discharge waveform recording unit 42, a partial-discharge amount-of-charge determination function provided by a partial-discharge amount-of-charge determining unit 43, an amount-of-change determination function for the partial-discharge amount-of-charge which is provided by an amount-of-change determining unit 44, an evaluation function provided by an evaluation unit 45 (a material estimation function provided by a material estimating unit 45a), a correlation-information generation function provided by a correlation-information generation unit 46, and so on.

### [Partial-Discharge Waveform Recording Unit]

While the voltage application unit 2 applies a voltage to the sample 100, partial discharge occurs, so that charge is generated in the sample 100 and is detected by the partial-discharge detecting unit 3. The partial-discharge waveform recording unit 42 is configured so as to continuously measure and record the detected charge.

More specifically, for example, two data loggers 42a and 42b, which serve as the partial-discharge waveform recording unit 42, are connected to the two opposite ends of the capacitor 3a (see FIG. 2). The data loggers 42a and 42b are configured so as to measure a terminal voltage of the capacitor 3a. Each of the data loggers 42a and 42b is configured so as to record information of the measured terminal voltage, for example, in the form of waveform data as illustrated in FIG. 3. Each of the data loggers 42a and 42b is configured so as to create, for example, as a single file, information of the terminal voltage of the capacitor 3a recorded by a single operation between the stop of the operation and the start of the next operation. The data loggers 42a and 42b are configured so as to add time information (e.g., information for specifying a time that has elapsed from the start of voltage application) to the recorded information of the terminal voltage of the capacitor 3a.

The partial-discharge amount-of-charge determining unit 43 (described below) is electrically connected to the data loggers 42a and 42b (the partial-discharge waveform recording unit 42). The data loggers 42a and 42b are configured so as to send (transfer) the information of the terminal voltage of the capacitor 3a to the partial-discharge amount-of-charge determining unit 43, for example, in the form of waveform data at a predetermined timing.

A timer mechanism 42c is connected to the data loggers 42a and 42b (see FIG. 2). The timer mechanism 42c is configured so to monitor a predetermined time (e.g., 10 seconds) and so as to issue, to the data loggers 42a and 42b, an instruction for switching the operations of the data loggers 42a and 42b at the intervals of the predetermined time.

Mainly, the two data loggers 42a and 42b constitute the partial-discharge waveform recording unit 42. The timer mechanism 42c may be regarded as being included in the partial-discharge waveform recording unit 42.

### [Partial-Discharge Amount-of-Charge Determining Unit]

Upon obtaining (receiving) the information of the terminal voltage of the capacitor 3a (e.g., the waveform data illustrated in FIG. 3) from the partial-discharge waveform recording unit 42, the partial-discharge amount-of-charge determining unit 43 executes a predetermined program that describes a procedure for determining the partial-discharge amount-of-charge and so on, to thereby determine the partial-discharge amount-of-charge. The term “partial-discharge amount-of-charge” as used herein refers to the amount of charge generated in the sample 100 owing to the occurrence of partial discharge. For example, at intervals of a predetermined unit time (e.g., 10 seconds) and for each pulse of the waveform data obtained by the partial-discharge waveform recording unit 42, the partial-discharge amount-of-charge determining unit 43 calculates the partial-discharge amount-of-charge for each file sent from the partial-discharge waveform recording unit 42.

The partial-discharge amount-of-charge determining unit 43 is configured so as to determine partial-discharge amount-of-charge, for example, by using a residual charge method. That is, the partial-discharge amount-of-charge determining unit 43 is configured so as to determine the partial-discharge amount-of-charge by calculating a residual voltage in the capacitor 3a which is due to partial discharge that occurs in the sample 100 and calculating a product of the electrostatic capacitance and the residual voltage of the capacitor 3a. More specifically, on the basis of the data of the terminal voltage of the capacitor 3a, the data being received from the partial-discharge waveform recording unit 42, the partial-discharge amount-of-charge determining unit 43 determines the residual voltage in the capacitor 3a by using a difference between the terminal voltage of the capacitor 3a before the partial discharge occurs in the sample 100 and the terminal voltage of the capacitor 3a after the partial discharge occurs in the sample 100. Also, in accordance with Coulomb's law, the partial-discharge amount-of-charge determining unit 43 multiplies the determined residual voltage in the capacitor 3a by the electrostatic capacitance in the capacitor 3a to determine the amount of charge (the amount of residual charge) that remains in the capacitor 3a and regards the determined amount of residual charge as the partial-discharge amount-of-charge in the sample 100.

For example, when the partial-discharge amount-of-charge determining unit 43 receives the waveform data, illustrated in FIG. 3, from the partial-discharge waveform recording unit 42 as the data of the terminal voltage of the capacitor 3a, the partial-discharge amount-of-charge determining unit 43 determines the partial-discharge amount-of-charge in the sample 100 by using equation (1) below. The solid line in FIG. 3 indicates the terminal voltage of the capacitor 3a when no partial discharge occurs, and the dotted line in FIG. 3 indicates the terminal voltage of the capacitor 3a when partial discharge occurs.

Q=Cd×(|V2−V1|+|V3−V2|) (1)

In equation (1), Q represents the amount of charge generated in the sample 100 (the amount of residual charge in the capacitor 3a) owing to the partial discharge, Cd represents the electrostatic capacitance of the capacitor 3a, and V1, V2, and V3 each indicate a value of a difference between the terminal voltage of the capacitor 3a when partial discharge occurs and the terminal voltage when no partial discharge occurs.

The amount-of-change determining unit 44 (described below) is electrically connected to the partial-discharge amount-of-charge determining unit 43. The partial-discharge amount-of-charge determining unit 43 sends (transfers) the information of the determined partial-discharge amount-of-charge to the amount-of-change determining unit 44. The partial-discharge amount-of-charge determining unit 43 sends, to the amount-of-change determining unit 44 (described below), the information of the partial-discharge amount-of-charge in the form of waveform data indicating a relationship between the partial-discharge amount-of-charge, for example, as illustrated in FIG. 4, and the time in which the voltage application unit 2 applies the voltage to the sample 100.

### [Amount-of-Change Determining Unit]

Upon receiving the information of the partial-discharge amount-of-charge (e.g., the waveform data illustrated in FIG. 4) from the partial-discharge amount-of-charge determining unit 43, the amount-of-change determining unit 44 executes a predetermined program that describes a procedure for determining the amount of change over time in the partial-discharge amount-of-charge (the amount of change in the partial-discharge amount-of-charge) and so on, to thereby determine the amount of change in the partial-discharge amount-of-charge.

For example, when the amount-of-change determining unit 44 receives waveform data B illustrated in FIG. 4 from the partial-discharge amount-of-charge determining unit 43 as the information of the partial-discharge amount-of-charge, the amount-of-change determining unit 44 detects a largest or smallest position in the waveform data B and determines the amount of change over time in the partial-discharge amount-of-charge (the rate of change, i.e., the gradient of the graph) in a predetermined time (e.g., 10 seconds) from the largest position or smallest position. The amount of change in the partial-discharge amount-of-charge differs depending on the type of insulating layer included in the sample 100, that is, depending on the material of the insulating layer. That is, when the material of the insulating layer is the same, the value of the amount of change in the partial-discharge amount-of-charge also becomes the same.

The evaluation unit 45 and the correlation-information generation unit 46 are electrically connected to the amount-of-change determining unit 44. The amount-of-change determining unit 44 is configured so as to send information of the determined amount of change in the partial-discharge amount-of-charge to the evaluation unit 45 (the material estimating unit 45a) or the correlation-information generation unit 46, described below.

### [Evaluation Unit]

Upon receiving the information of the amount of change in the partial-discharge amount-of-charge from the amount-of-change determining unit 44, the evaluation unit 45 reads and obtains correlation information, generated by the correlation-information generation unit 46 (described below), from the database unit 41, and evaluates the insulating layer by using the amount of change in the partial-discharge amount-of-charge on the basis of the correlation information. For example, the evaluation unit 45 includes the material estimating unit 45a for estimating the material (the composition or formation material) of the insulating layer included in the sample 100 and a thickness estimating unit 45b for estimating the thickness of the insulating layer. The evaluation unit 45 sends the result of the evaluation to an information output unit 5 (described below).

Upon receiving the information of the amount of change in the partial-discharge amount-of-charge from the amount-of-change determining unit 44, the material estimating unit 45a obtains, as the correlation information, information for identifying the material of the insulating layer, and compares the amount of change in the partial-discharge amount-of-charge in the sample 100 with the correlation information to estimate the material of the insulating layer.

Upon receiving the information of the amount of change in the partial-discharge amount-of-charge from the amount-of-change determining unit 44, the thickness estimating unit 45b obtains, as the correlation information, information for identifying the material of the insulating layer, and compares the amount of change in the partial-discharge amount-of-charge in the sample 100 with the correlation information to estimate the thickness of the insulating layer.

### [Correlation-Information Generation Unit]

The correlation-information generation unit 46 generates the correlation information about the amount of change in the partial-discharge amount-of-charge. The correlation-information generation unit 46 generates, as the correlation information, information for identifying the material and the thickness of the insulating layer, for example, by using the amount of change in the partial-discharge amount-of-charge. That is, the correlation-information generation unit 46 generates the correlation information by associating the information of the material and the thickness of the insulating layer with the amount of change in partial-discharge amount-of-charge for an electrical wire 100A (hereinafter also referred to as a “reference sample 100A”) having an insulating layer whose material and thickness are known in advance, the amount of change being determined by the amount-of-change determining unit 44. For example, the correlation-information generation unit 46 generates correlation information about each of a plurality of electrical wires having insulating layers whose materials and thicknesses are different. The correlation-information generation unit 46 sends the generated correlation information to the database unit 41. That is, the correlation-information generation unit 46 stores and holds the generated correlation information in the database unit 41.

For example, a display or the like, which serves as the information output unit 5, is connected to the control unit 4. Information about the result of processing performed by the control unit 4 is output and displayed on the information output unit 5. For example, information about the result of estimating the material of the insulating layer in the sample 100 is displayed on the information output unit 5.

### (2) Evaluation Method

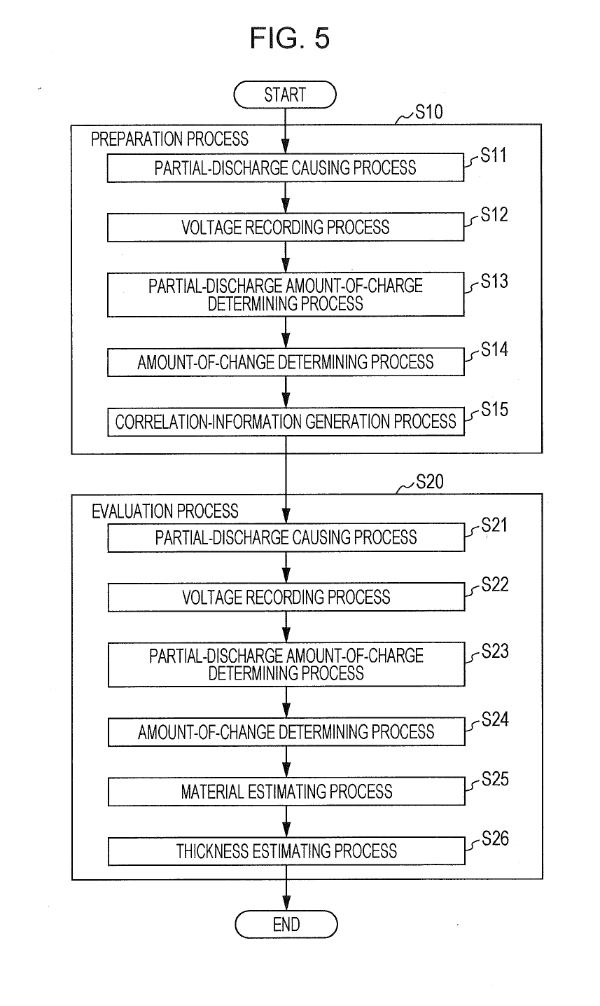

Next, a procedure for evaluating the electrical wire (the sample 100) by using the evaluation apparatus 1 will be described with reference to FIG. 5. FIG. 5 is a flow diagram illustrating a process for evaluating an electrical wire according to the present embodiment. In the present embodiment, a case in which the sample 100 is evaluated by estimating the material and thickness of an insulating layer in the sample 100 will be described as an example.

### (Preparation Process (S10))

With respect to an electrical wire 100A (a reference sample 100A) having an insulating layer whose material (composition or formation material) and thickness are known in advance, the amount of change in the partial-discharge amount-of-charge is determined, and correlation information is generated. In a preparation process (S10), correlation information about each of a plurality of electrical wires in insulating layers having different materials and thicknesses is generated.

### [Partial-Discharge Causing Process (S11)]

First, the voltage application unit 2 continuously applies a voltage higher than the voltage of the PDIV of the reference sample 100A to the reference sample 100A for a predetermined time, to cause partial discharge in the sample 100A.

### [Voltage Recording Process (S12)]

The partial-discharge detecting unit 3 detects charge generated in the reference sample 100A owing to partial discharge during a partial-discharge causing process (S11), and the partial-discharge waveform recording unit 42 continuously measures and records the charge detected by the partial-discharge detecting unit 3. That is, at the same time the voltage application unit 2 starts applying a voltage to the reference sample 100A, the operations of the data loggers 42a and 42b, which serve as the partial-discharge waveform recording unit 42, are started to start the measurement and recording of the terminal voltage of the capacitor 3a. More specifically, in accordance with the result of the monitoring performed by the timer mechanism 42c, the data loggers 42a and 42b are operated alternately at predetermined time intervals (e.g., 10 seconds) to continuously measure the terminal voltage of the capacitor 3a and record the terminal voltage of the capacitor 3a. At this point, the data loggers 42a and 42b may be operated at the same time for a predetermined time. At least while the voltage application unit 2 applies a voltage to the reference sample 100A, the partial-discharge waveform recording unit 42 continuously measures and records the charge detected by the partial-discharge detecting unit 3.

When excessive amount of charge is accumulated in the capacitor 3a while the partial-discharge waveform recording unit 42 records the terminal voltage of the capacitor 3a, the short-circuiting circuit 3b connected to the two opposite ends of the capacitor 3a is operated to short-circuit the two opposite ends of the capacitor 3a to discharge the accumulated charge. It is preferable that, for example, the short-circuiting circuit 3b be operated at predetermined intervals from when the voltage application unit 2 starts applying a voltage to the sample 100. This can suppress accumulation of excessive charge in the capacitor 3a, thus making it possible to more accurately measure the terminal voltage of the capacitor 3a.

After the terminal voltage of the capacitor 3a is recorded, each of the data loggers 42a and 42b sends the data of the terminal voltage of the capacitor 3a, the data being recorded by a single operation, to the partial-discharge amount-of-charge determining unit 43, for example, as one file, in a period from the stop of the operation and the start of the next operation. At this point, the data loggers 42a and 42b send (transfer) the recorded information of the terminal voltage of the capacitor 3a, for example, in the form of waveform data to the partial-discharge amount-of-charge determining unit 43. Also, each of the data loggers 42a and 42b adds time information to information to be sent to the partial-discharge amount-of-charge determining unit 43.

### [Partial-Discharge Amount-of-Charge Determining Process (S13)]

When the partial-discharge amount-of-charge determining unit 43 receives the information of the terminal voltage of the capacitor 3a from the data loggers 42a and 42b, the partial-discharge amount-of-charge determining unit 43 uses, for example, a residual charge method to determine the amount of charge (the amount of residual charge) that remains in the capacitor 3a, on the basis of the received information of the terminal voltage of the capacitor 3a, and regards the determined amount of residual charge as the partial-discharge amount-of-charge discharged from the reference sample 100A. For example, the partial-discharge amount-of-charge determining unit 43 determines the partial-discharge amount-of-charge for every period of one operation of the data loggers 42a and 42b (i.e., each time operation switching occurs). That is, the partial-discharge amount-of-charge determining unit 43 determines the partial-discharge amount-of-charge for each file received from the data loggers 42a and 42b. When the partial-discharge amount-of-charge is determined, the determined partial-discharge amount-of-charge is temporarily stored in a RAM or the like that is accessible by the partial-discharge amount-of-charge determining unit 43. When the partial-discharge amount-of-charge determining unit 43 determines the partial-discharge amount-of-charge until the voltage application unit 2 finishes the application of a voltage to the reference sample 100A, the partial-discharge amount-of-charge determining unit 43 sends the information of the determined partial-discharge amount-of-charge to the amount-of-change determining unit 44. For example, the partial-discharge amount-of-charge determining unit 43 creates waveform data indicating the relationship between the partial-discharge amount-of-charge and the voltage application time of the reference sample 100A, on the basis of the information of the partial-discharge amount-of-charge, and sends the created waveform data to the amount-of-change determining unit 44.

### [Amount-of-Change Determining Process (S14)]

When the partial-discharge amount-of-charge determining process (S13) ends, and the amount-of-change determining unit 44 receives the information of the partial-discharge amount-of-charge in the reference sample 100A from the partial-discharge amount-of-charge determining unit 43, the amount-of-change determining unit 44 determines the amount of change in the partial-discharge amount-of-charge in the reference sample 100A. More specifically, first, the amount-of-change determining unit 44 detects a largest position or a smallest position in the received waveform data. When the waveform data has a plurality of largest positions or smallest positions, the amount-of-change determining unit 44 detects all of the largest positions or smallest positions in the waveform data. The amount-of-change determining unit 44 determines the amount of change in the partial-discharge amount-of-charge for a predetermined time (e.g., 10 seconds) from each largest position or smallest position. Upon determining the amount of change in the partial-discharge amount-of-charge, the amount-of-change determining unit 44 sends the information of the determined amount of change to the correlation-information generation unit 46.

### [Correlation-Information Generation Process (S15)]

When the amount-of-change determining process (S14) ends, and the correlation-information generation unit 46 receives the information of the amount of change in the partial-discharge amount-of-charge in the reference sample 100A from the amount-of-change determining unit 44, the correlation-information generation unit 46 generates correlation information about the amount of change in the partial-discharge amount-of-charge. More specifically, the correlation-information generation unit 46 generates the correlation information by associating the information of the material of the insulating layer and the information of the thickness of the insulating layer with the amount of change in the partial-discharge amount-of-charge determined for the reference sample 100A. The correlation-information generation unit 46 then sends the generated correlation information to the database unit 41, so that the correlation information is stored and held in the database unit 41.

### (Evaluation Process (S20))

When the preparation process (S10) ends, the amount of change in the partial-discharge amount-of-charge is determined for the electrical wire (the sample 100) that is to be evaluated and that has an insulating layer whose material and thickness are unknown, and the material of the insulating layer is estimated to evaluate the electrical wire.

### [Partial-Discharge Causing Process (S21)]

First, the voltage application unit 2 applies a voltage higher than the voltage of the PDIV of the sample 100 to the sample 100 for a predetermined time (e.g., 20000 seconds), to thereby cause partial discharge in the sample 100.

### [Voltage Recording Process (S22)]

The data loggers 42a and 42b, which serve as the partial-discharge waveform recording unit 42, continuously measure and record the charge generated in the sample 100 owing to the occurrence of partial discharge and detected by the partial-discharge detecting unit 3. That is, as in the above-described voltage recording process (S12), the charge generated in the sample 100 owing to the partial discharge and detected by the partial-discharge detecting unit 3 is recorded. The partial-discharge waveform recording unit 42 sends (transfers) the information of the recorded terminal voltage of the capacitor 3a for the sample 100 to the partial-discharge amount-of-charge determining unit 43, for example, in the form of waveform data.

### [Partial-Discharge Amount-of-Charge Determining Process (S23)]

When the partial-discharge amount-of-charge determining unit 43 receives the information of the terminal voltage of the capacitor 3a from the partial-discharge waveform recording unit 42, the partial-discharge amount-of-charge determining unit 43 determines the amount of charge (the amount of residual charge) that remains in the capacitor 3a, on the basis of the received information of the terminal voltage of the capacitor 3a, and regards the determined amount of residual charge as the partial-discharge amount-of-charge discharged from the sample 100. That is, the partial-discharge amount-of-charge in the sample 100 is determined, as in the partial-discharge amount-of-charge determining process (S13) described above. When the partial-discharge amount-of-charge determining unit 43 determines the partial-discharge amount-of-charge until the voltage application unit 2 finishes the application of a voltage to the sample 100, the partial-discharge amount-of-charge determining unit 43 sends the information of the partial-discharge amount-of-charge to the amount-of-change determining unit 44. For example, the partial-discharge amount-of-charge determining unit 43 sends the information of the partial-discharge amount-of-charge to the amount-of-change determining unit 44 in the form of waveform data indicating the relationship between the partial-discharge amount-of-charge and the voltage application time.

### [Amount-of-Change Determining Process (S24)]

When the partial-discharge amount-of-charge determining process (S23) ends, and the amount-of-change determining unit 44 receives the information of the partial-discharge amount-of-charge from the partial-discharge amount-of-charge determining unit 43, the amount-of-change determining unit 44 determines the amount of change in the partial-discharge amount-of-charge in the sample 100. That is, the amount of change in the partial-discharge amount-of-charge in the sample 100 is determined, as in the amount-of-change determining process (S14) described above. Upon determining the amount of change in the partial-discharge amount-of-charge in the sample 100, the amount-of-change determining unit 44 sends information of the determined amount of change to the material estimating unit 45a.

### [Material Estimating Process (S25)]

When the amount-of-change determining process (S24) ends, and the material estimating unit 45a, which serves as the evaluation unit 45, receives the information of the amount of change in the partial-discharge amount-of-charge in the sample 100, the material estimating unit 45a estimates the material of the insulating layer, on the basis of the amount of change in the partial-discharge amount-of-charge. More specifically, when the material estimating unit 45a receives the information of the amount of change in the partial-discharge amount-of-charge in the sample 100, the material estimating unit 45a reads the correlation information from the database unit 41. On the basis of the read correlation information, the material estimating unit 45a estimates the material of the insulating layer by using the amount of change in the partial-discharge amount-of-charge. More specifically, the material estimating unit 45a compares the amount of change in the partial-discharge amount-of-charge in the sample 100 with the correlation information to detect correlation information about the amount of change in the partial-discharge amount-of-charge which matches the amount of change in the partial-discharge amount-of-charge in the sample 100. The expression “amount of change in the partial-discharge amount-of-charge” includes a case in which the amount of change in the partial-discharge amount-of-charge matches substantially, in addition to a case in which the amount of change in the partial-discharge amount-of-charge matches completely. The material estimating unit 45a obtains the information of the material of the insulating layer, the information being associated with the detected correlation information, and estimates that the obtained information of the material of the insulating layer indicates the material of the insulating layer of the sample 100.

The material estimating unit 45a sends the estimation result of the material of the insulating layer of the sample 100 to the information output unit 5 as an evaluation result. Information of the evaluation result is output from the information output unit 5.

### [Thickness Estimating Process (S26)]

After the material estimating process (S25) ends, the thickness estimating unit 45b estimates the thickness of the insulating layer of the sample 100 on the basis of the correlation information read by the material estimating unit 45a. That is, the thickness estimating unit 45b obtains the information of the thickness of the insulating layer, the information being associated with the correlation information read by the material estimating unit 45a, and estimates the thickness of the insulating layer of the sample 100. When the materials of the insulating layers are the same, and the times of the voltage applied from the voltage application unit 2 are the same, the thickness of the insulating layer and the partial-discharge amount-of-charge have a certain relationship (e.g., a proportional relationship) therebetween. That is, when the thickness of the insulating layer is reduced, the value of the partial-discharge amount-of-charge decreases. Thus, the thickness estimating unit 45b determines the ratio of the partial-discharge amount-of-charge in the reference sample 100A versus the partial-discharge amount-of-charge in the sample 100 for the same voltage application time. For example, the amount-of-change determining unit 44 creates the waveform data illustrated in FIG. 4, and when waveform data A in FIG. 4 is used as data of the sample 100, and the waveform data B is used as data of the reference sample 100A, the ratio of the partial-discharge amount-of-charge at a largest position in the waveform data A versus the partial-discharge amount-of-charge at a largest position in the waveform data B is determined. The determined ratio and the thickness of the insulating layer of the reference sample 100A are used to determine the thickness of the sample 100, and the determined thickness is used as an estimation result of the thickness of the sample 100.

The thickness estimating unit 45b sends the estimation result of the thickness of the insulating layer of the sample 100 to the information output unit 5 as an evaluation result. Information of the evaluation result is then output from the information output unit 5.

### (3) Advantage of Present Embodiment

The present embodiment offers one or more advantages described below.

(a) According to the present embodiment, the amount of change in the partial-discharge amount-of-charge is used as an index for evaluation. This makes it possible to easily and accurately evaluate an electrical wire, for example, estimate the material of the insulating layer. That is, we have found the correlation that the amount of change in the partial-discharge amount-of-charge is the same when the material of an insulating layer in the sample 100 is the same, and thus it is possible to easily and accurately estimate the material of the insulating layer. For example, it is possible to suppress changes in the evaluation result which occur due to a temperature or the like during estimation of the material of an insulating layer. Also, for estimating the material of an insulating layer, there is no need to remove the insulating layer from, the electrical wire.

The present embodiment is effective when it is difficult to remove an insulating layer from an electrical wire, for example, when the thickness of an insulating layer is small (e.g., a few, micrometers or less).

(b) Even when an insulating layer is constituted by a plurality of layers, the use of the amount of change in the partial-discharge amount-of-charge as an index for evaluation makes it possible to estimate the material for each layer in the insulating layer. That is, when an insulating layer is constituted by an inside layer and an outside layer sequentially from the conductor side, application of a voltage from the voltage application unit 2 to the sample 100 first causes partial discharge in the outside layer. Then, after the dielectric breakdown, in which the insulator in the outside layer is broken and the insulation state cannot be maintained, partial discharge occurs in the inside layer. Accordingly, when changes in the partial-discharge amount-of-charge are measured over time, the partial-discharge amount-of-charge in the outside layer is first recorded, and then the partial-discharge amount-of-charge in the inside layer is recorded. Thus, it is possible to estimate the material for each layer in the insulating layer without removing each layer in the insulating layer. It is, therefore, possible to offer the advantage (a) described above.

(c) The use of the amount of change in the partial-discharge amount-of-charge as an index for evaluation makes it possible to easily estimate the thickness of the insulating layer. That is, when the materials of insulating layers are the same, and the times of voltages applied from the voltage application unit 2 are the same, the thicknesses of the insulating layers and the partial-discharge amount-of-charge have a correlation, that is, a certain relationship (e.g., a proportional relationship), therebetween. Thus, by associating the information of the thickness of an insulating layer with the correlation information and identifying the material of the insulating layer by using the amount of change in the partial-discharge amount-of-charge, it is possible to estimate the thickness of the insulating layer of the sample 100 on the basis of the ratio of the partial-discharge amount-of-charge in the reference sample 100A versus the partial-discharge amount-of-charge in the sample 100 for the same voltage application time.

(d) The control unit 4 can also estimate the material of the insulating layer of the sample 100 by automatically determining the amount of change in the partial-discharge amount-of-charge on the basis of the determination result of the partial-discharge amount-of-charge in the sample 100. Thus, the material of an insulating layer can be estimated in a shorter period of time.

(e) In the present embodiment, the two data loggers 42a and 42b are used as the partial-discharge waveform recording unit 42, and the data loggers 42a and 42b are alternately operated to continuously measure and record the partial discharge. All of the partial discharge that occurs in the sample 100 (the reference sample 100A) and that is detected by the partial-discharge detecting unit 3 can be measured and recorded. Thus, it is possible to more accurately estimate the material of an insulating layer.

### Other Embodiments of Present Invention

Although one embodiment of the present invention has been specifically described above, the present invention is not limited to the above-described embodiment, and changes and modifications can be made thereto without departing from the scope thereof.

Although, in the above embodiment, the thickness of an insulating layer is estimated in the thickness estimating process (S26) on the basis of the correlation information read by the material estimating unit 45a in the material estimating process (S25), the present disclosure is not limited thereto. That is, upon receiving the information of the amount of change in the partial-discharge amount-of-charge in the sample 100, the thickness estimating unit 45b may read the correlation information from the database unit 41 and estimate the thickness of an insulating layer by using the amount of change in the partial-discharge amount-of-charge on the basis of the read correlation information.

Although, in the above embodiment, the thickness estimating process (S26) is performed after the material estimating process (S25), the present disclosure is not limited thereto. For example, the material estimating process (S25) may be performed after the thickness estimating process (S26). Also, the material estimating process (S25) and the thickness estimating process (S26) may be performed in parallel. Although the material estimating process (S25) and the thickness estimating process (S26) are performed, the present disclosure is not limited thereto. That is, either the material estimating process (S25) or the thickness estimating process (S26) may be performed.

Although, in the above embodiment, the amount of change in the partial-discharge amount-of-charge in the sample 100 is compared with the correlation information to evaluate the insulating layer, the present disclosure is not limited thereto. That is, estimation and evaluation of an insulating layer in an electrical wire may be performed using changes in the partial-discharge amount-of-charge over time without comparing the amount of change in the partial-discharge amount-of-charge in the sample 100 with the correlation information.

For example, through defection of changes over time in the partial-discharge amount-of-charge in the sample 100, it can be evaluated by estimating that the insulating layer in the sample 100 is a layer (anti-surge layer) that has an anti-surge characteristic, when the partial-discharge amount-of-charge decreases over time, and by estimating that the insulating layer is a layer (general-purpose layer) that does not have an anti-surge characteristic, when the partial-discharge amount-of-charge increases over time.

Also, for example, by detecting changes in the partial-discharge amount-of-charge over time, it is possible to estimate a layer configuration of an insulating layer. As described above, the amount of change in the partial-discharge amount-of-charge in an insulating layer differs depending on the material that forms the insulating layer. Thus, observing changes in the partial-discharge amount-of-charge over time and observing changes in the amount of change in the partial-discharge amount-of-charge makes it possible to estimate a layer configuration of the insulating layer. For example, when the amount-of-change determining unit 44 creates the waveform data illustrated in FIG. 4, it can be estimated that the insulating layer has a two-layer structure in which an anti-surge layer and a general-purpose layer are stacked sequentially from the conductor side.

Although a case in which, in the amount-of-change determining process (S14 and S24), a largest or smallest position in the waveform data is detected and the amount of change in the partial-discharge amount-of-charge for a predetermined time is determined based on the largest or smallest position has been described in the above embodiment, the present disclosure is not limited thereto. That is, it is sufficient that the amount of displacement in the partial-discharge amount-of-charge for the same voltage application time be determined between the amount-of-change determining process (S14) and the amount-of-change determining process (S24). For example, the amount of change in the partial-discharge amount-of-charge for a predetermined time from an arbitrary portion between a largest position and a smallest position may be determined. Also, for waveform data that does not have a largest or smallest position, the amount of change in the partial-discharge amount-of-charge for a predetermined time from an arbitrary position in the waveform data may be determined. For a predetermined time after the voltage application unit 2 starts applying a voltage to the sample 100 (the reference sample 100A), a motor for driving the voltage application unit 2 is exposed to a high voltage pulse having a short rise time. Thus, in this period of time, there are cases in which a correct partial-discharge amount-of-charge in the sample 100 (the reference sample 100A) cannot be determined. Thus, it is desirable that, in a period of time other than that period of time, the amount of change in the partial-discharge amount-of-charge be determined.

A case in which the preparation process (S10) is performed has been described in the above embodiment. However, when the correlation information about the amount of change in the partial-discharge amount-of-charge is already generated for the reference sample 100A that is the same type as the sample 100 and is stored and held in the database unit 41, there is no need to perform the preparation process (S10). That is, when the correlation information already exists in the database unit 41, the preparation process (S10) does not necessarily have to be executed.

Although a case in which the partial-discharge detecting unit 3 uses a residual charge method to detect charge generated in the sample 100 owing to the occurrence of partial discharge has been described in the above embodiment, the present disclosure is not limited thereto. For example, the partial-discharge detecting unit 3 may detect the partial discharge by using discharged-current/voltage waveform measurement based on a detection impedance method, a differential detection method using high-frequency computed tomography (CT), and so on.

Although the two data loggers 42a and 42b are used as the partial-discharge waveform recording unit 42 in the embodiment described above, the present disclosure is not limited thereto. For example, one data logger or three or more data loggers may be used as the partial-discharge waveform recording unit 42.

### Preferable Aspects of the Present Invention

Appendices of preferred aspects of the present invention will be given below.

### [Aspect 1]

According to one aspect of the present invention, there is provided a method for evaluating an electrical wire having a conductor and an insulating layer. The method includes: a partial-discharge amount-of-charge determining step of applying, by a voltage application unit, a voltage to the electrical wire to cause partial discharge in the electrical wire and determining an amount of charge owing to the partial discharge; and an evaluation step of evaluating the insulating layer by using a change over time in the amount of charge owing to the partial discharge.

### [Aspect 2]

Preferably, the method according to aspect 1 further includes an amount-of-change determining step of determining an amount of change over time in the amount of charge determined in the partial-discharge amount-of-charge determining step. In the evaluation step, correlation information about the amount of change may be obtained, and the insulating layer may be evaluated by using the amount of change, based on the correlation information.

### [Aspect 3]

In the method according to aspect 2, preferably, in the evaluation step, information for identifying a material of the insulating layer by using the amount of change is obtained as the correlation information, and the amount of change determined in the amount-of-change determining step is compared with the correlation information to estimate the material of the insulating layer.

### [Aspect 4]

In the method according to one of aspects 1 to 3, preferably, in the evaluation step, a layer configuration of the insulating layer may be estimated by using changes in the amount of charge over time.

### [Aspect 5]

In the method according to one of aspects 2 to 4, preferably, in the evaluation step, information for identifying a thickness of the insulating layer by using the amount of change is obtained as the correlation information, and the amount of change determined in the amount-of-change determining step is compared with the correlation information to estimate a composition of the insulating layer.

### [Aspect 6]

The method according to one of aspects 1 to 5 further includes a correlation-information generation step of continuously detecting, for a predetermined time, an amount of charge owing to partial discharge in another electrical wire having a same type of insulating layer as the insulating layer in the electrical wire, generating the correlation information by using a result of the detection, and storing and holding the correlation information. In the evaluation step, the correlation information may be obtained by reading the correlation information stored and held in the correlation-information generation step.

### [Aspect 7]

According to another aspect of the present invention, there is provided an apparatus for evaluating an electrical wire. The apparatus includes: a voltage application unit that applies a voltage to an electrical wire having a conductor and an insulating layer; a partial-discharge amount-of-charge determining unit that determines an amount of charge owing to partial discharge that occurs in the electrical wire; and an evaluation unit that evaluates the insulating layer by using a change over time in the amount of charge owing to the partial discharge.

What is claimed is:

1. A method for evaluating an electrical wire having a conductor and an insulating layer, the method comprising:
a partial-discharge amount-of-charge determining step of applying, by a voltage application unit, a voltage to the electrical wire to cause partial discharge in the electrical wire and determining an amount of charge owing to the partial discharge; and
an evaluation step of evaluating the insulating layer by using a change over time in the amount of charge owing to the partial discharge.

2. The method according to claim 1, further comprising:
an amount-of-change determining step of determining an amount of change over time in the amount of charge determined in the partial-discharge amount-of-charge determining step,
wherein, in the evaluation step, correlation information about the amount of change is obtained, and the insulating layer is evaluated by using the amount of change, based on the correlation information.

3. The method according to claim 2,
wherein, in the evaluation step, information for identifying a material of the insulating layer by using the amount of change is obtained as the correlation information, and the amount of change determined in the amount-of-change determining step is compared with the correlation information to estimate the material of the insulating layer.

4. The method according to claim 1, further comprising:
a correlation-information generation step of continuously detecting, for a predetermined time, an amount of charge owing to partial discharge in another electrical wire having a same type of insulating layer as the insulating layer in the electrical wire, generating the correlation information by using a result of the detection, and storing and holding the correlation information,
wherein, in the evaluation step, the correlation information is obtained by reading the correlation information stored and held in the correlation-information generation step.

5. An apparatus for evaluating an electrical wire, the apparatus comprising:
a voltage application unit that applies a voltage to an electrical wire having a conductor and an insulating layer;
a partial-discharge amount-of-charge determining unit that determines an amount of charge owing to partial discharge that occurs in the electrical wire; and
an evaluation unit that evaluates the insulating layer by using a change over time in the amount of charge owing to the partial discharge.
